(19) United States
(12) Patent Application Publication
(10) Pub. No.: US 2019/0371992 A1
(43) Pub. Date: Dec. 5, 2019

(54) HIGH RESISTANCE THERMOELECTRIC ELEMENT

(71) Applicant: Faurecia Automotive Seating, LLC, Auburn Hills, MI (US)

(72) Inventor: Shaun Dorian Tait, Troy, MI (US)

(21) Appl. No.: 15/991,186

(22) Filed: May 29, 2018

(51) Int. Cl. H01L 35/04; H01L 35/32; F25B 21/02; H01L 27/16

(52) U.S. Cl. CPC H01L 35/04; H01L 27/16; F25B 21/02; H01L 35/32

(57) ABSTRACT

A thermoelectric element includes a resistor in series with a thermoelement pair to effectively limit the electric current therethrough. This construction enables placement of individual or small numbers of thermoelements in parallel without exceeding the maximum current threshold of the thermoelements. Such parallel arrangements eliminate the need to serially connect large numbers of thermoelectric elements, offering design freedom and preventing total device failure when a single thermoelectric element fails.

### TECHNICAL FIELD

The present disclosure relates to thermoelectric devices and, in particular, thermoelectric devices for use in vehicles.

### BACKGROUND

Thermoelectric devices are solid-state electrically powered heat pumps that rely on the Peltier effect to provide a temperature difference along their opposite sides. The Peltier effect is exhibited when a DC voltage is applied and current flows across a junction of two dissimilar materials. The temperature of the junction will either increase or decrease in temperature, depending on the polarity of the applied voltage and the resulting direction of current flow. Conventional thermoelectric devices are relatively small electronic devices in which the dissimilar materials include an n-type semiconductor paired with a p-type semiconductor with the junction formed between them. Thermoelectric devices typically include multiple pairs of such materials arranged electrically in series to provide a corresponding multiple number of junctions. This effectively scales up the energy transfer capacity of the device, which is proportional to the number of junctions. It also makes the device practical for use with commonly available DC voltages, such as a 12-volt automotive electrical system.

In WO 2007/109368, Lindstrom et al. teach a thermoelectric device with electric current carrying substrates that allow higher current carrying capacity between individual thermoelements of the device via the use of electrical conductors on both the interior and the exterior sides of the substrates. The thermoelements are electrically connected in series between the substrates, and the exterior conductors perform an additional function as strengthening elements.

### SUMMARY

In accordance with one or more embodiments, a thermoelectric device includes a first electrode, a second electrode, a thermoelement pair, and a resistor. The first electrode is adapted for connection with one pole of a power source, and the second electrode adapted for connection with an opposite pole of the power source. The thermoelement pair includes first and second thermoelements electrically coupled together to form a thermoelectric junction. One of the thermoelements is a p-type thermoelement, and the other of the thermoelements is an n-type thermoelement. The resistor is arranged in electrical series with the thermoelement pair such that, when connected to the power source, a voltage drop across the thermoelement pair is less than a voltage across the poles of the power source.

In some embodiments, the thermoelectric junction is electrically insulated from the first and second electrodes.

In some embodiments, the thermoelectric device includes a first electrical lead, a first insulating layer, a second electrical lead, and a second insulating layer. The first electrical lead couples a first end of the first thermoelement to a first end of the second thermoelement to form the thermoelectric junction. The first insulating layer is located between the first electrical lead and the first electrode to insulate the first electrical lead from the first electrode. The second electrical lead couples a second end of the first thermoelement to the second electrode. The second insulating layer is located between a second end of the second thermoelement and the second electrode to insulate the second end of the second thermoelement from the second electrode. The resistor may be connected across the first electrode and the second end of the second thermoelement, or the resistor may be in-line with a power lead adapted to connect one of the electrodes to the power source.

In some embodiments, the device includes another resistor with one resistor connected across the first electrode and the second end of the second thermoelement and the other resistor in-line with the power lead.

In some embodiments, the thermoelement pair is one of a plurality of thermoelement pairs arranged in electrical series with the resistor. When connected to the power source, a combined voltage drop across the plurality of thermoelement pairs is less than the voltage across the poles of the power source. Each of the thermoelement pairs includes respective p-type and n-type thermoelements electrically coupled together to form respective thermoelectric junctions.

In some embodiments, the thermoelectric device includes a first plurality of electrical leads, a first insulating layer, a second electrical lead, and a second insulating layer. Each electrical lead of the first plurality connects respective first ends of the thermoelements of each thermoelement pair to form the thermoelectric junction of each pair. The first insulating layer is located between the first plurality of electrical leads and the first electrode to insulate the first plurality of electrical leads from the first electrode. The second electrical lead couples a second end of the first thermoelement of one of the thermoelement pairs to the second electrode. The second insulating layer is located between the second electrode and a second end of the second thermoelement of a different one of the thermoelement pairs to insulate the second electrode from the second end of the second thermoelement of said different one of the thermoelement pairs. The resistor may be connected across the first electrode and the second end of the second thermoelement of said different one of the thermoelement pairs, or the resistor may be in-line with a power lead adapted to connect one of the electrodes to the power source.

In some embodiments, the thermoelectric device includes another resistor with one resistor connected across the first electrode and the second end of the second thermoelement of said different one of the thermoelement pairs and the other resistor in-line with the power lead.

In some embodiments, a body of the resistor is in contact with one of the electrodes.

Various aspects, embodiments, examples, features and alternatives set forth in the preceding paragraphs, in the claims, and/or in the following description and drawings may be taken independently or in any combination thereof. For example, features disclosed in connection with one embodiment are applicable to all embodiments in the absence of incompatibility of features.

### BRIEF DESCRIPTION OF THE DRAWINGS

Exemplary embodiments will hereinafter be described in conjunction with the appended drawings, wherein like designations denote like elements, and wherein:

FIG. 1 illustrates an embodiment of a thermoelectric element for use in a thermoelectric device, including a resistor in series with a thermoelement pair;

FIG. 2 illustrates the thermoelectric element with an additional resistor in series with the thermoelement pair;

FIG. 3 illustrates the thermoelectric element with the resistor in-line with a power lead;

FIG. 4 illustrates the thermoelectric element with a body of the resistor in contact with an electrode; and

FIG. 5 illustrates the thermoelectric element with the resistor in series with two thermoelement pairs.

### DETAILED DESCRIPTION

The thermoelectric element described below is configured to effectively limit the electric current therethrough and enables placement of individual or small numbers of thermoelements in parallel without exceeding a maximum current threshold of the thermoelements. Such parallel arrangements can eliminate the need to serially connect large numbers of thermoelectric elements, offering design freedom and preventing total device failure when a single thermoelectric element of thermoelectric device fails.

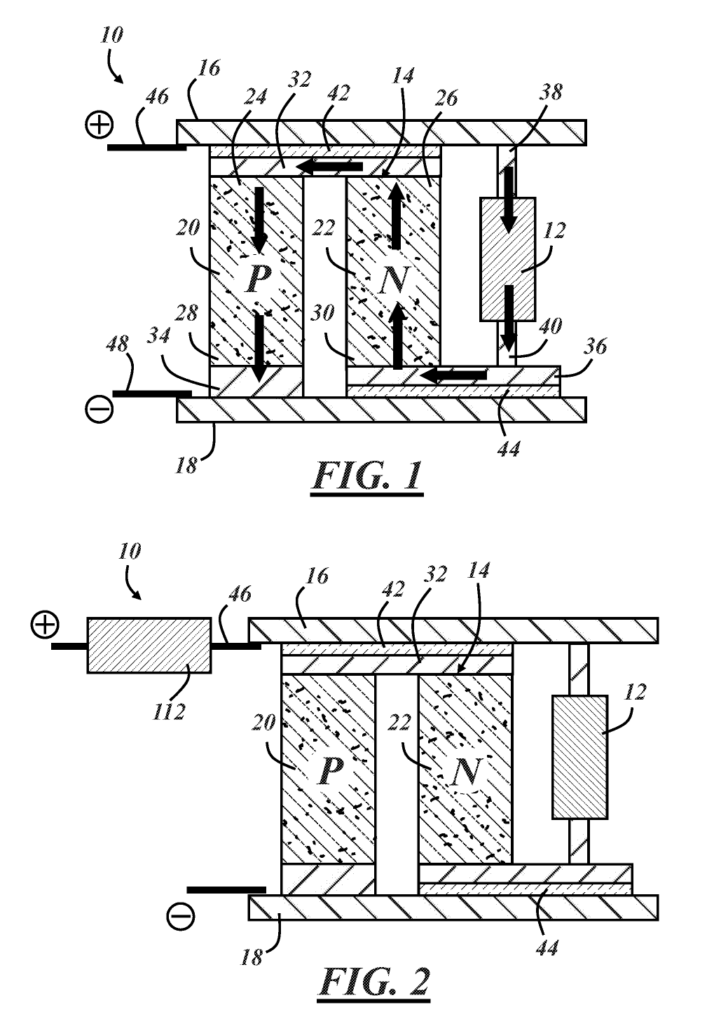

FIG. 1 illustrates an embodiment of a thermoelectric element 10 for use in a thermoelectric device. The thermoelectric element 10 includes a resistor 12 arranged in electrical series with a thermoelement pair 14 between first and second electrodes 16, 18. The thermoelement pair 14 includes a first thermoelement 20 and a second thermoelement 22. The first thermoelement 20 is made from a p-type semiconductor and may be referred to as a P-element. The second thermoelement 22 is made from an n-type semiconductor with a Peltier coefficient complementary to that of the p-type semi-conductor and may be referred to as an N-element. Each thermoelement 20, 22 has a first end 24, 26 proximate the first electrode 16 and an opposite second end 28, 30 proximate the second electrode 18. The thermoelements 20, 22 of the pair 14 are electrically coupled together to form a thermoelectric junction, which in this case is in the form of an electrical lead 32 connecting their first ends 24, 26. The direction of electric current flow across the thermoelectric junction 32 determines which is the “hot” side and which is the “cold” side of the thermoelectric element 10. Current flow across the junction 32 from the N-element to the P-element as shown tends to cause heat to flow in a direction from the first ends 24, 26 toward the second ends 28, 30 of the thermoelements, making the illustrated thermoelectric junction 32 the “cold” side of the thermoelement pair 14. Stated differently, heat and electric current flow in the same direction along the P-element in the regardless of the direction of current flow.

The example of FIG. 1 includes a second electrical lead 34 that couples the second end 28 of the P-element to the second electrode 18. The resistor 12 is connected across the first electrode 16 and the second end 30 of the N-element via a third electrical lead 36 in the illustrated embodiment. In particular, a first end 38 of the resistor 12 is connected to the first electrode 16, and an opposite second end 40 of the resistor is connected to the second end 30 of the N-element via the third electrical lead 36. Only one of the illustrated electrical leads—the second lead 34—is in direct contact with either one of the electrodes 16, 18. A first electrically insulating layer 42 is located between the first electrical lead 32 and the first electrode 16, and a second electrically insulating layer 44 is located between the third electrical lead 36 and the second electrode 18.

When connected to a DC power source via power leads 46, 48, a circuit is formed with the resistor 12 in electrical series with the thermoelement pair 14. With the first electrode 16 as the positive electrode and the second electrode 18 as the negative electrode as shown, current flows through the thermoelectric element 10 from the first electrode 16 to the second electrode 18 sequentially through the resistor 12, the N-element 22, and the P-element 20. Other arrangements are possible. For instance, the relative positions of the resistor 12 and thermoelement pair 14 could be reversed so that current flows through the thermoelectric pair first and/or the P- and N-elements could be in reverse serial order. As such, it should be appreciated that the indicator words “first,” “second,” etc. are used generically and are not intended to limit the claims to the illustrated and described embodiments. For example, the first electrode may by the positive or negative electrode, the first electrical lead may be any lead connecting the serially arranged elements of the circuit, etc.

The size of the resistor 12 is a function of the applied voltage, the effective resistance of the thermoelement pair 14, and the current carrying capacity of the thermoelement pair. In its simplest terms,

$$R = \frac{V}{{I}_{max}} - {R}_{TE} , \qquad ( 1 )$$

where R is the resistance of the resistor 12, V is the voltage of the power source, Iₘₐₓ is the current carrying capacity of the thermoelement pair 14, and R_{TE} is the effective resistance of the thermoelement pair. Other factors or system variables may need to be considered, such as the impedance of the power source, the resistance of the electrodes, electrical leads, power leads, and other electrical connections within the thermoelectric element, temperature dependence of the variables, etc. Also, Iₘₐₓ may be a current rating for the thermoelement pair rather than a maximum failure current. Skilled artisans will be able to select a suitable resistance value for the resistor 12 without undue experimentation with the understanding that the resistor functions to limit current through the thermoelectric pair 14.

In one non-limiting example in a vehicle application in which the vehicle operates on a 12-VDC electrical system, a single thermoelement pair with a rated current capacity Iₘₐₓ of 4 amperes and an effective resistance R_{TE} of 15 milliohms is placed in series with a resistor have a resistance R of 2.985 ohms. Without the resistor, application of 12 volts across the low resistance thermoelement pair could result in several hundred amps of current, which would blow a fuse in the vehicle electrical system and/or burn the thermoelement pair like a fuse. This is why a conventional thermoelectric device for use with a 12-VDC vehicle system typically includes approximately 200 thermoelement pairs arranged in series with each other. These numbers are of course only used as a non-limiting example and are presented here with easily divisible numbers for purposes of simplicity in explanation. Skilled artisans will appreciate, for example, that a 12-VDC vehicle electrical system usually operates in a range of voltages closer to 15 volts. Additionally, certain resistance values may require the use of more than one resistor in series with the thermoelement pair.

The disclosed thermoelectric element 10 can be placed in parallel electrical arrangements with other thermoelectric elements 10 that a thermoelectric device with a plurality of thermoelement pairs can be made without upper or lower limits on the number of thermoelement pairs in the device. Conventional thermoelectric devices are limited to a minimum number of thermoelement pairs required to limit the total current through the device to a level each individual thermoelement pair can accommodate, and they are limited to a maximum number of thermoelement pairs above which the current is insufficiently low for the thermoelement pair to exhibit the thermoelectric effect. This configuration may provide much greater design freedom with the possibility of any number of thermoelectric elements of a thermoelectric device arranged in parallel or in various combinations of series and parallel. A thermoelectric device with thermoelectric elements arranged in parallel can continue to function if and when one of the thermoelectric elements fails, unlike conventional thermoelectric devices in which the failure of one thermoelement pair means failure of the entire device. The effect can be significant in conventional thermoelectric devices with approximately 200 thermoelement pairs, for example. A 0.05% thermoelement failure rate among numerous conventional thermoelectric devices would mean a 10% average overall device failure rate. In contrast, a 0.05% thermoelement failure rate among numerous thermoelectric devices with the disclosed thermoelectric element would lead to an overall device failure rate of 0%. Instead, about 10% of the resulting thermoelectric devices would operate with a thermoelectric capacity reduced by 0.5%.

FIG. 2 illustrates the thermoelectric element 10 with an additional resistor 112 in series with the thermoelement pair 14. In this particular case, the additional resistor is in-line with one of the power leads 46. The operating principle is generally the same as in the example of FIG. 1 with the pair of resistors 12, 112 operating to limit current flow through the thermoelement pair 14. In other examples, the additional resistor 112 could be in-line with the other power lead 48, each of the two resistors could be in-line with a different one of the power leads, or more than two resistors can be employed. The resistance of each resistor 12, 112 can be determined based on the same methodology in equation (1) above using R=R₁+R₂, with R₁ and R₂ being respective resistance values for each resistor. In some embodiments, the resistor 12 located between the electrodes 16, 18 has a lower resistance than that of the additional resistor 112. In a non-limiting example, the additional resistor 112 is sized so that a voltage drop across the additional resistor is more than half and up to 99% of the applied voltage. Locating the resistor with the higher resistance value outside the opposed faces of the electrodes 16, 18 may help with heat management of the element.

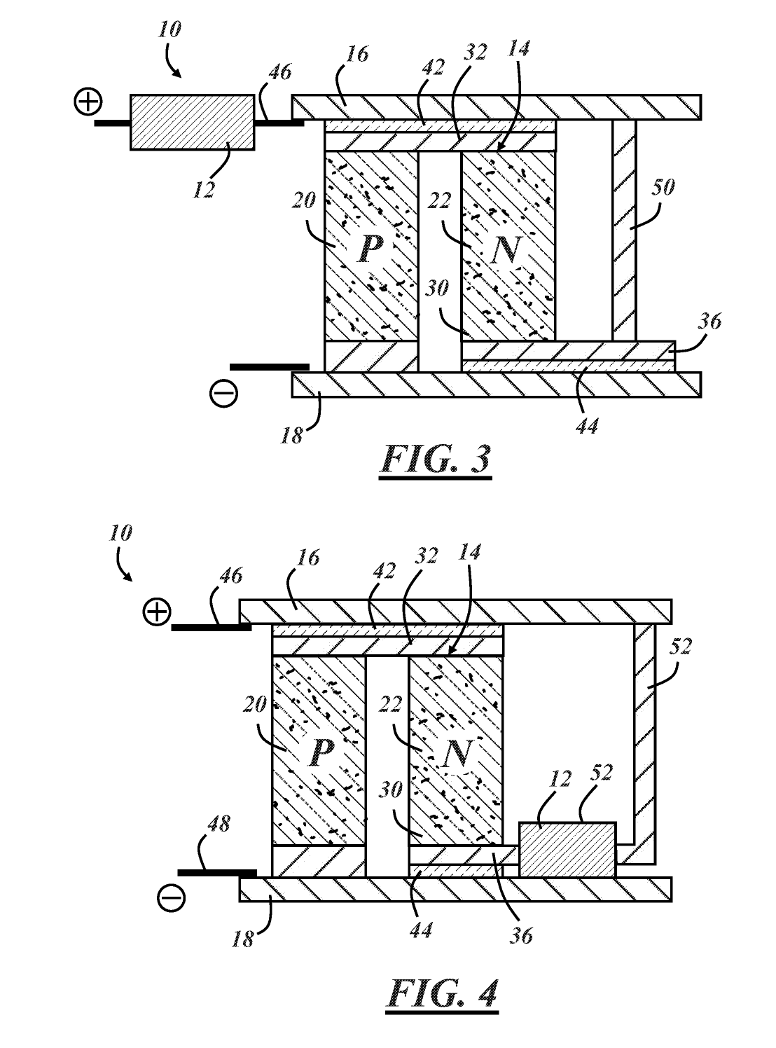

In the example of FIG. 3, the current through the thermoelement pair 14 of the thermoelectric element 10 is limited by a single resistor 12 as in FIG. 1, with the resistor located in-line with one of the power leads 46 similar to the additional resistor 112 of FIG. 2. The operating principle is the same as described above with the resistance of the resistor 12 based generally on equation (1). This configuration includes an additional electrical lead 50 interconnecting the first electrode 16 with the second end 30 of the N-element 22 via the third electrical lead 36. Locating the resistor 12 outside the opposed faces of the electrodes 16, 18 may help with heat management of the element.

In the example of FIG. 4, a body 52 of the resistor 12 is in physical thermally conductive contact with the second electrode 18. The body 52 of the resistor 12 is electrically insulating. As in the example of FIG. 1, the resistor 12 is connected across the first electrode 16 and the second end 30 of the N-element 22 via third electrical lead 36, which may be a lead of the resistor 12, an electrically conductive layer deposited on the N-element, or a combination of both. Similarly, an electrical lead 52 that forms part of the resistive connection between the first electrode 16 and the N-element 22 may be a lead of the resistor 12 or a separately provided lead interconnecting a lead of the resistor 12 with the first electrode 16. Current flow through the thermoelectric element 10 of FIG. 4 is the same as in FIG. 1, defining the second electrode 18 side of the element as the “hot” side. In thermoelectric device applications, the hot side of the device may be active cooled by forced convection along a heat sink or by some other heat exchange means. Placement of the resistor body 52 in contact with the electrode on the defined hot side of the element 10 may help with heat management with at least some of the heat generated by the resistor 12 being dissipated with the heat generated by the thermoelement pair 14 and absorbed from the opposite side of the element. This configuration can be used in combination with those described above—i.e., an additional resistor can be placed in series with the thermoelement pair 14 either between the electrodes 16, 18 or in-line with one or both of the power leads 46, 48.

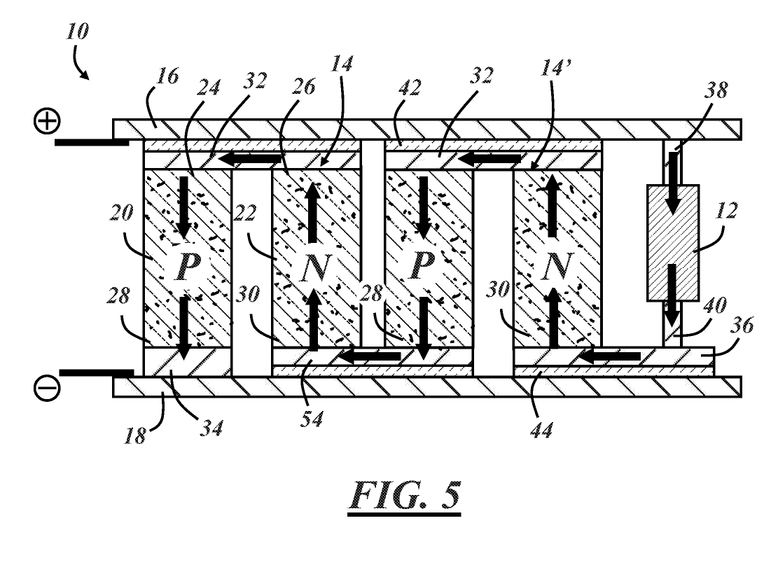

FIG. 5 illustrates the thermoelectric element 10 configured with the resistor 12 in series with two thermoelement pairs 14, 14′ between the first and second electrodes 16, 18. Stated differently, the thermoelement pair 14 of FIG. 1 is one of a plurality of thermoelement pairs arranged in electrical series with the resistor 12 such that a combined voltage drop across the plurality of thermoelement pairs is less than the voltage across the poles of the power source, with the resistor 12 accounting for the remainder of the voltage drop. The resistor 12, or multiple resistors as discussed above, serves to limit the current flow through the thermoelectric element to an acceptable level for the thermoelement pairs.

Each of the thermoelement pairs 14, 14′ includes respective p-type and n-type thermoelements 20, 22 electrically coupled together to form respective thermoelectric junctions at their first ends 24, 26 in the form of electrical leads 32. The electrical leads 32 connecting the individual thermoelements 20, 22 of each pair 14, 14′ may be considered together as a discontinuous conductive layer that defines a plurality of electrical leads 32 each connecting respective first ends 24, 26 of the thermoelements of each pair to form the thermoelectric junction of each pair.

In this example, the second electrical lead 34 couples the second end 28 of the P-element of one of the thermoelement pairs 14 to the second electrode 18, and the resistor 12 is connected across the first electrode 16 and the second end 30 of the N-element of the other thermoelectric pair 14′ via the third electrical lead 36. The first end 38 of the resistor 12 is connected to the first electrode 16, and the opposite second end 40 of the resistor is connected to the second end 30 of the N-element via the third electrical lead 36. An additional electrical lead 54 proximate the second electrode 18 interconnects the two thermoelement pairs 14, 14′. In particular, the electrical lead 54 connects the second end 30 of the N-element of one thermoelement pair 14 to the second end 28 of the P-element of the other thermoelement pair 14′. The electrical lead 54 connecting one thermoelement pair 14 to the other thermoelement pair 14′ may be considered together with the third conductive lead 36 as a discontinuous conductive layer that could define additional discrete electrical leads in embodiments including more than two thermoelement pairs.

As in FIG. 1, only one of the illustrated electrical leads—the second lead 34—is in direct contact with one of the electrodes 18. The first electrically insulating layer 42 is located between the plurality of first electrical leads 32 and the first electrode 16, and the second electrically insulating layer 44 insulates the other electrical leads 36, 54 from the second electrode 18. Each insulating layer 42, 44 in this example is illustrated here in discrete segments associated with different electrical leads 32, 36, 54. But each may be considered a single discontinuous layer or formed as a continuous layer.

Operation of the example of FIG. 5 is the same as in the previous examples, with the resistor sized to limit the current through the element 10 to a tolerable level for the individual thermoelement pairs 14, 14′. When connected to the power source, a circuit is formed with the resistor 12 in electrical series with both thermoelement pairs 14, 14′. Current flows through the thermoelectric element 10 from the first electrode 16 to the second electrode 18 sequentially through the resistor 12, the N-element of one pair 14′, the P-element of the same pair, and the N-element then P-element of the other pair 14. Other arrangements are possible such as combinations of features from the examples of FIGS. 1-4.

The resistance of the resistor 12 in the example of FIG. 5 can be made smaller than in the previous examples with the resistance of the thermoelectric pairs being constant. The resistance can be determined based on the same methodology in equation (1) above using R_{TE}=nRₜₑ, where Rₜₑ is the resistance of a single thermoelement pair, and n is the number of thermoelement pairs placed in series with the resistor. The configuration of FIG. 5 may be more energy efficient that the previous examples while largely maintaining the above-stated advantages associated with enabling parallel connections among multiple thermoelectric elements of a thermoelectric device.

While the resistors in the examples above are illustrated as traditional axial-lead resistors with a fixed resistance, other types of resistors may be used, such as radial-lead or surface mount (SMT) resistors. It is also possible to employ a resistor with variable resistance that, for example, changes resistance with changing voltage of the power supply to ensure proper current limitation during high voltage peaks. Other electronic devices such as voltage regulators could be used in series with the thermoelement pairs to provide a current-limiting function and may be considered a resistor in that sense.

Placing a resistor in series with a single or small number of thermoelement pairs may be considered a method of limiting the electrical current through the thermoelement pairs. The method may include providing a power source having a voltage and providing a thermoelement pair having an electrical resistance and an electric current threshold, wherein an electric current resulting from applying the voltage across the thermoelement pair is greater than the electric current threshold. The method may further include limiting the current flow through the thermoelectric pair by placing an electronic component, such as a resistor, in series with the thermoelectric pair before completing the circuit.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “for instance,” “such as,” and “like,” and the verbs “comprising,” “having,” “including,” and their other verb forms, when used in conjunction with a listing of one or more components or other items, are each to be construed as open-ended, meaning that that the listing is not to be considered as excluding other, additional components or items. Other terms are to be construed using their broadest reasonable meaning unless they are used in a context that requires a different interpretation.

1. A thermoelectric device, comprising:
a first electrode adapted for connection with one pole of a power source;
a second electrode adapted for connection with an opposite pole of the power source;
a thermoelement pair including first and second thermoelements electrically coupled together to form a thermoelectric junction, wherein one of the thermoelements is a p-type thermoelement and the other of the thermoelements is an n-type thermoelement; and
a resistor arranged in electrical series with the thermoelement pair such that, when connected to the power source, a voltage drop across the thermoelement pair is less than a voltage across the poles of the power source.

2. A thermoelectric device as defined in claim 1, wherein the thermoelectric junction is electrically insulated from the first and second electrodes.

3. A thermoelectric device as defined in claim 1, further comprising:
a first electrical lead that couples a first end of the first thermoelement to a first end of the second thermoelement to form the thermoelectric junction;
a first insulating layer located between the first electrical lead and the first electrode to insulate the first electrical lead from the first electrode;
a second electrical lead that couples a second end of the first thermoelement to the second electrode; and
a second insulating layer located between a second end of the second thermoelement and the second electrode to insulate the second end of the second thermoelement from the second electrode.

4. A thermoelectric device as defined in claim 3, wherein the resistor is connected across the first electrode and the second end of the second thermoelement.

5. A thermoelectric device as defined in claim 3, wherein the resistor is in-line with a power lead adapted to connect one of the electrodes to the power source.

6. A thermoelectric device as defined in claim 5, further comprising another resistor connected across the first electrode and the second end of the second thermoelement.

7. A thermoelectric device as defined in claim 1, wherein a body of the resistor is in contact with one of the electrodes.

8. A thermoelectric device as defined in claim 1, wherein the thermoelement pair is one of a plurality of thermoelement pairs arranged in electrical series with the resistor such that, when connected to the power source, a combined voltage drop across the plurality of thermoelement pairs is less than the voltage across the poles of the power source, each of the thermoelement pairs including respective p-type and n-type thermoelements electrically coupled together to form respective thermoelectric junctions.

9. A thermoelectric device as defined in claim 8, further comprising:
a first plurality of electrical leads, each connecting respective first ends of the thermoelements of each thermoelement pair to form the thermoelectric junction of each pair;
a first insulating layer located between the first plurality of electrical leads and the first electrode to insulate the first plurality of electrical leads from the first electrode;
a second electrical lead that couples a second end of the first thermoelement of one of the thermoelement pairs to the second electrode; and
a second insulating layer located between the second electrode and a second end of the second thermoelement of a different one of the thermoelement pairs to insulate the second electrode from the second end of the second thermoelement of said different one of the thermoelement pairs.

10. A thermoelectric device as defined in claim 9, wherein the resistor is connected across the first electrode and the second end of the second thermoelement of said different one of the thermoelement pairs.

11. A thermoelectric device as defined in claim 9, wherein the resistor is in-line with a power lead adapted to connect one of the electrodes to the power source.

12. A thermoelectric device as defined in claim 11, further comprising another resistor connected across the first electrode and the second end of the second thermoelement of said different one of the thermoelement pairs.

13. A thermoelectric device as defined in claim 8, wherein a body of the resistor is in contact with one of the electrodes.
